(19) United States
(12) Patent Application Publication
(10) Pub. No.: US 2025/0194272 A1
(43) Pub. Date: Jun. 12, 2025

(54) SEMICONDUCTOR PHOTODETECTOR

(71) Applicant: STMicroelectronics International N.V., Geneva (CH)

(72) Inventor: Arthur ARNAUD, La Tronche (FR)

(73) Assignee: STMicroelectronics International N.V., Geneva (CH)

(21) Appl. No.: 18/970,137

(22) Filed: Dec. 5, 2024

(30) Foreign Application Priority Data
Dec. 7, 2023 (FR) FR2313769

(51) Int. Cl. H10F 39/00

(52) U.S. Cl. CPC H10F 39/8033; H10F 39/014; H10F 39/807

(57) ABSTRACT

A semiconductor photodetector includes an active region made of a doped semiconductor material of a first conductivity type. The active region is configured to convert a light radiation into charge carriers and to store the charge carriers. At least one repulsion element is positioned within the active region and configured to repel charge carriers stored in the active region.

### PRIORITY CLAIM

This application claims the priority benefit of French Application for Patent No. 2313769, filed on Dec. 7, 2023, the content of which is hereby incorporated by reference in its entirety to the maximum extent allowable by law.

### TECHNICAL FIELD

The present disclosure generally concerns electronic components and more specifically semiconductor photodetectors.

The present disclosure concerns, for example, photodiodes, vertical pinned photodiodes, or vertical photogates.

The present disclosure also concerns electronic devices, such as image sensors, comprising photodetectors.

### BACKGROUND

An image sensor may comprise a plurality of pixels organized in a network, for example an array, each pixel comprising one (or a plurality of) photodetector(s) configured to capture light rays (photons) and to converting them into charge carriers, that is, electrons and/or holes. This can be referred to as a photoconversion, or a photoelectric conversion. The generated charge carriers can be transferred into one (or a plurality of) circuit(s), such as a readout circuit, configured to convert the charge into electrical signals. The pixel array is generally associated with different circuits, such as control, readout and/or power supply circuits.

A plurality of photodetectors may be integrated inside and on top of a same semiconductor layer, for example, a silicon layer. The photodetectors may be insulated from one another by insulators, for example insulating trenches which extend across all or part of the thickness of the semiconductor layer. As an example, each photodetector comprises a photosensitive region integrated in the semiconductor layer, which may be designated by the term “active area” or “active region”. This active region corresponds to a region in which charge carriers are generated by conversion of light radiation and stored. The active region may be a depletion region of the semiconductor layer, which may be designated with the term “well”.

A photodetector may be a photodiode, which is a semiconductor component having a PN junction, generally formed by a junction between an N-type semiconductor region and a P-type semiconductor region. In operation, the photodiode is in reverse biasing mode. When the reverse-biased photodiode is exposed to photons, electron-hole pairs can be generated around the PN junction of the photodiode.

In particular, the photodiode may be a pinned photodiode. A pinned photodiode can be defined as a photodiode in which the active region comprises an N-type, respectively P-type, semiconductor region, surrounded by one or a plurality of P-type, respectively N-type, semiconductor regions. In this type of photodiode, the N-type active region is generally fully depleted by heavily P-type doped semiconductor regions. Thus, the electrons generated by conversion of light radiation are stored in the depleted N-type active region, while the holes are evacuated into the heavily P-type doped semiconductor regions. In the case of a P-type active region, depleted by heavily N-type doped semiconductor regions, the holes are stored in the active region, while the electrons are evacuated into the heavily N-type doped semiconductor regions.

A photodetector may be a photogate. A photogate can be defined as a photodetector in which the active region comprises an N-type semiconductor region and/or a P-type semiconductor region, in contact with a trench region of metal-oxide-semiconductor (MOS) type forming a bias gate. For example, in the case of an N-doped active region, the gate is negatively biased so that the active region is depleted throughout its volume to be able to store electrons, while the surface in contact with the gate oxide is in inversion to evacuate the photogenerated holes.

It may be desired to improve the performance of photodetectors, for example to improve the signal-to-noise ratio (SNR), to increase the dynamic range (DR), and/or to decrease the dark current (DC), for example by increasing the capacity of charge carrier storage in the active region of the photodetector, which can be designated by the term “full well capacity” (FWC).

There is a need in the art to overcome all or part of the disadvantages of known photodetectors;

### SUMMARY

An embodiment provides a semiconductor photodetector comprising: an active region made of a doped semiconductor material of a first conductivity type, said active region being configured to convert a light radiation into charge carriers and to store said charge carriers; and at least one repulsion element configured to repel charge carriers stored in the active region, said repulsion element being positioned within the active region.

An embodiment provides a method of manufacturing a semiconductor photodetector, the method comprising: forming an active region made of a doped semiconductor material of a first conductivity type, said active region being configured to convert a light radiation into charge carriers and to store said charge carriers; and forming at least one repulsion element configured to repel charge carriers stored in the active region, said repulsion element being formed within the active region.

According to an embodiment, the at least one repulsion element is arranged in the active region in such a way that it does not divide said active region into a plurality of distinct volumes.

According to an embodiment, the at least one repulsion element is surrounded by the active region in at least one plane.

According to an embodiment, the at least one repulsion element comprises a plurality of repulsion elements, for example a plurality of repulsion elements regularly distributed in the active region, for example a plurality of repulsion elements substantially equidistant from one another.

According to an embodiment, the at least one repulsion element is oriented in a longitudinal direction of the photodetector.

According to an embodiment, the at least one repulsion element is oriented in a transverse direction of the photodetector.

According to an embodiment, the at least one repulsion element has a shape of a continuous pillar, for example a pillar with a polygonal, rectangular, square, oval, or circular cross-section.

According to an embodiment, the at least one repulsion element comprises a plurality of implant points separated from one another by portions of the active region, for example forming a discontinuous pillar.

According to an embodiment, the at least one repulsion element extends from a first surface of the active region all the way to a non-zero distance from a second surface of the active region opposite to the first surface, a portion of the active region located between said at least one repulsion element and said second surface being, for example, heavily doped with the first conductivity type.

According to an embodiment, the at least one repulsion element comprises, for example is, an internal capacitive deep trench isolation, preferably configured to be biased so as to repel the stored charge carriers.

According to an embodiment, the at least one repulsion element comprises, for example is, a doped implant region of the second conductivity type opposite to the first conductivity type.

According to an embodiment, the photodetector further comprises a lateral insulating trench configured to laterally insulate said photodetector, for example from other photodetectors.

According to an embodiment, the insulating trench contains a conductive or semiconductor element, the insulating trench and the conductive or semiconductor element forming a lateral capacitive deep trench isolation.

According to an embodiment, the photodetector further comprises a lateral implant region between the lateral insulating trench and the active region, the lateral implant region being doped with the second conductivity type opposite to the first conductivity type.

According to an embodiment, the active region has a non-homogeneous doping, for example in one or a plurality of transverse directions of the photodetector.

An embodiment provides an image sensor comprising a plurality of pixels, each pixel comprising at least one photodetector such as previously described.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A shows, in a simplified perspective view, an example of a photodetector;

FIG. 1B shows, in a simplified perspective view, an example of a pixel with photodetectors;

FIG. 2 shows, in a perspective view, a photodetector according to an embodiment;

FIG. 3A shows, in a top cross-section view, a photodetector according to another embodiment;

FIG. 3B shows, in a transverse cross-section view, the photodetector of FIG. 3A;

FIG. 4A shows, in a top cross-section view, a photodetector according to another embodiment;

FIG. 4B shows, in a transverse cross-section view, the photodetector of FIG. 4A;

FIG. 5A shows, in a top cross-section view, a photodetector according to another embodiment;

FIG. 5B shows, in a transverse cross-section view, the photodetector of FIG. 5A;

FIG. 6A shows, in a top cross-section view, a photodetector according to another embodiment;

FIG. 6B shows, in a transverse cross-section view, the photodetector of FIG. 6A;

FIG. 7A shows, in a top cross-section view, a photodetector according to another embodiment;

FIG. 7B shows, in a transverse cross-section view, the photodetector of FIG. 7A;

FIG. 8A shows, in a top cross-section view, a photodetector according to another embodiment;

FIG. 8B shows, in a transverse cross-section view, the photodetector of FIG. 8A;

FIG. 9A shows, in a top cross-section view, a photodetector according to another embodiment;

FIG. 9B shows, in a transverse cross-section view, the photodetector of FIG. 9A;

FIG. 10A shows, in a top cross-section view, a photodetector according to another embodiment;

FIG. 10B shows, in a transverse cross-section view, the photodetector of FIG. 10A;

FIGS. 11A to 11E show, in top cross-section views, photodetectors according to other embodiments;

FIGS. 12A to 12G show, in transverse cross-section views, steps of an example of a method of manufacturing a photodetector according to an embodiment;

FIGS. 13A to 13E show, in transverse cross-section views, steps of another example of a method of manufacturing a photodetector according to another embodiment; and

FIGS. 14A to 14E show curves representing different characteristics of pixels with photodetectors according to embodiments as compared with subdivided photodetector pixels of the type of FIG. 1B.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, not all the circuits of a photodetector, for example a memory and/or a readout circuit, are detailed, the embodiments being compatible with all or most photodetector circuits, possibly subject to adaptations within the abilities of those skilled in the art on reading of the present disclosure. Further, a photodetector has been mainly shown, knowing that this photodetector may be integrated in an electronic device, for example in an image sensor pixel, and a pixel may comprise one or a plurality of photodetectors. Further, not all the applications of photodetectors are detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings, or to a photodetector as orientated during normal use.

Unless specified otherwise, the expressions “about”, “approximately”, “substantially”, and “in the order of” signify plus or minus 10%, preferably of plus or minus 5%.

In the following description, a height or a depth corresponds to a dimension taken in the Z direction, corresponding to the longitudinal or lateral direction of the photodetector, which may be a vertical direction, a length corresponds to a dimension taken in the Y direction, corresponding to a first transverse direction of the photodetector, which may be a first horizontal direction, and a width corresponds to a dimension taken in the X direction, perpendicular to the Y direction, corresponding to a second transverse direction of the photodetector, which may be a second horizontal direction.

In the following description, when reference is made to a region, it is referred, unless otherwise specified, to a semiconductor region. In the following description, when reference is made to a charge, it is referred, unless otherwise specified, to a charge carrier, that is, an electron or a hole.

In the following description, the expression “active region” of a photodetector designates a region from which the majority of the light radiation received by the photodetector is collected and/or a region from which the majority of the light radiation emitted by the photodetector is emitted.

In the examples given hereafter, it is considered that the first conductivity type is type N and that the second conductivity type is type P, but the examples may also apply if the conductivity types are reversed, that is, the first conductivity type is type P and the second conductivity type is type N with, for example, appropriate voltage inversions applied to the CDTIs.

The present disclosure concerns photodetectors. Photodiodes, for example pinned photodiodes, and photogates, especially vertical pinned photodiodes and vertical photogates, are particularly considered.

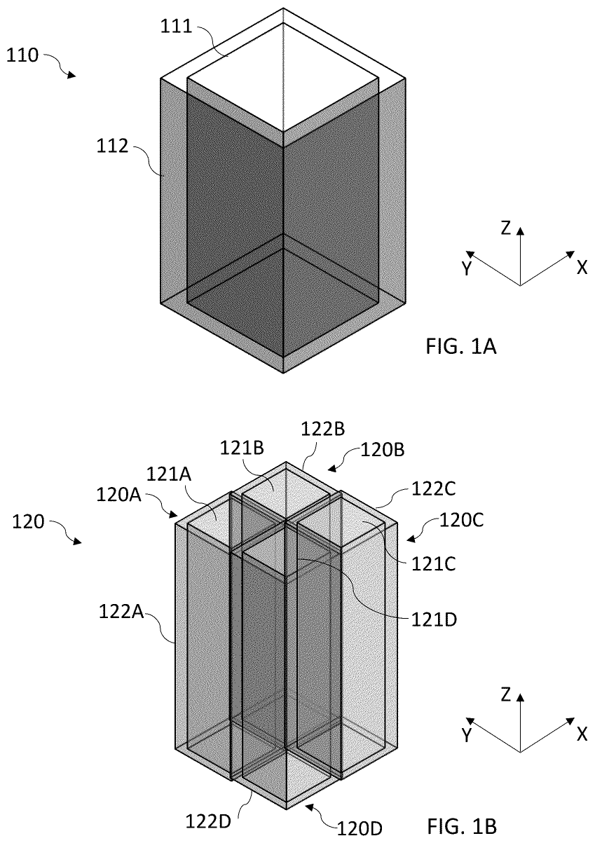

FIG. 1A shows, in a simplified perspective view, an example of a photodetector 110, which may be a photogate of a pixel. In this example, photodetector 110 comprises an N-doped active region 111, surrounded with a capacitive deep trench isolation (CDTI) 112. The capacitive deep trench isolation is typically an insulating trench filled with a conductive or semiconductor element, such as metal or polysilicon, which may be biased, thus forming a bias gate. The capacitive deep trench isolation 112 also enables to isolate the photodetector, for example, from other photodetectors. Active region 111 may correspond to a region of a semiconductor layer (not shown), such as silicon. With an N-doped active region, the biasing applied to the CDTI is preferably negative in order to deplete the active region.

To improve the performance of such a photodetector, for example to improve the signal-to-noise ratio (SNR), increase the dynamic range (DR), and/or decrease the dark noise (i.e., dark current (DC)), it may be attempted to increase the storage capacity of charge carriers in the active region of the photodetector, which can be designated by the term full well capacity (FWC).

A known solution to increase the full well capacity (FWC) consists of increasing the doping in the active region. A problem with increasing the doping is that this results in decreasing the depletion effect and thus requires increasing the biasing of the capacitive deep trench isolation to be able to deplete the active region, for example causing an increase in the power consumption of an image sensor comprising these photodetectors.

It may then be attempted to decrease the size of the photodetector, at the same time as the doping is increased, to decrease the biasing of the CDTI, and to increase the resolution of the photodetector, but this then decreases the full well capacity. This is generally referred to as a pixel size decrease.

A solution to increase the photodetector performance may then consist in dividing the pixel into a plurality of sub-pixels, each sub-pixel corresponding to a photodetector having an active region surrounded by a capacitive deep trench isolation, and then grouping the charges of a plurality of adjacent sub-pixels. This technique is known under the term pixel binning, or binning, which can be defined as being a technique of combination of the charges of adjacent pixels, for example by adding or averaging these charges, due to multiple pixel readouts.

FIG. 1B shows, in a simplified perspective view, an example of a pixel with photodetectors 120. FIG. 1B illustrates the solution described hereabove.

The pixel with photodetectors 120 comprises in this example four active regions 121A, 121B, 121C, 121D, each surrounded by a CDTI 122A, 122B, 122C, 122D. For example, each active region surrounded by a CDTI forms a photodetector 120A, 120B, 120C, 120D, or sub-pixel.

This solution enables to improve the capacity of storage of the charge carriers of the equivalent pixel, corresponding to the binned adjacent sub-pixels, without having to increase the biasing of the CDTIs, but this is achieved at the cost of a more complex technology, particularly in terms of CDTI powering, as well as of signals reading and processing. For example, if the equivalent pixel corresponds to n adjacent sub-pixels, n signals have to be read and processed, instead of a single signal if the pixel had not been divided. Further, this results in decreasing variation of the signal-to-noise ratio, which varies like the square root of the number of sub-pixels.

There is a need to increase the charge carrier full well capacity of a photodetector, and this, without having to increase the biasing of the active region, and/or without having to increase the number of charge readouts.

The inventors provide photodetectors enabling to address the previously-described improvement needs, and to overcome all or part of the disadvantages of the previously-described photodetectors.

Embodiments of photodetectors will be described hereafter. The described embodiments are non-limiting and different variants will occur to those skilled in the art based on the indications of the present description.

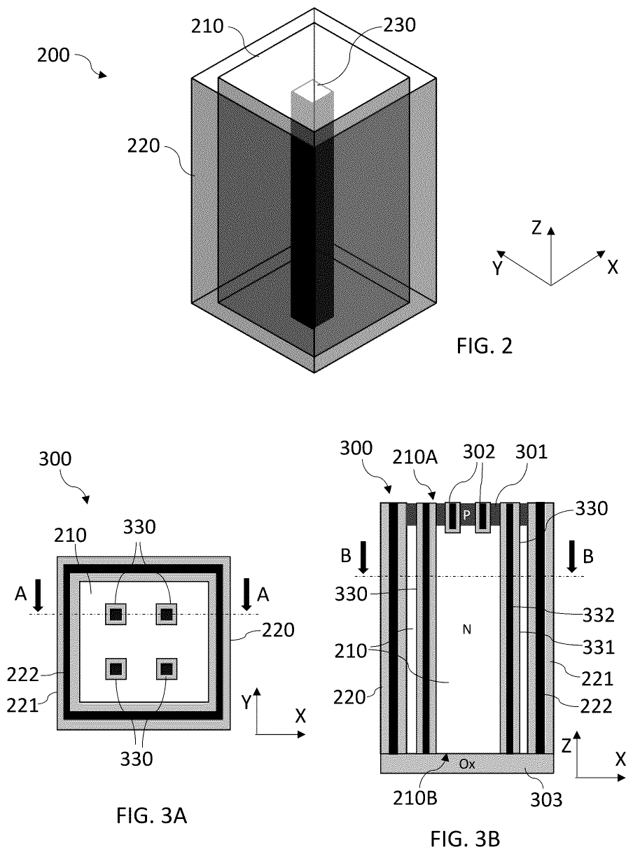

FIG. 2 shows, in a perspective view, a photodetector 200 according to embodiment.

Photodetector 200 comprises, similarly to the photodetector 110 of FIG. 1A, an N-type, for example N-doped, active region 210 surrounded by a lateral capacitive deep trench isolation (CDTI) 220, or external CDTI, but mainly differs therefrom in that it further comprises an element 230 for repelling the charges stored in active region 210, this repulsion element being positioned within active region 210. In the shown example, repulsion element 230 is arranged substantially at the center of the active region 210, where the electrostatic control by the external CDTI is generally the weakest, but variants are possible.

In the case of an N-doped active region, the repulsion element is an element for repelling the photogenerated electrons stored in the active region. In the case of a P-doped active region, the repulsion element is an element for repelling the photogenerated holes stored in the active region.

This element is defined as being a repulsion element in that it enables to improve the depletion of the active region and to repel a type of photogenerated charge carrier towards the active region.

Active region 210 is, for example, an N-doped portion of a silicon (Si) layer, for example an epitaxial silicon layer.

In the example of FIG. 2, the lateral capacitive deep trench isolation 220 forms a ring of square cross-section around active region 210, which is parallelepipedal, but other shapes and configurations will occur to those skilled in the art. For example, there may be a plurality of external CDTIs.

As can be seen in further detail in FIG. 3B for example, the lateral capacitive deep trench isolation 220 comprises an insulating trench 221, for example made of silicon dioxide (SiO₂), filled with a conductive or semiconductor element 222, such as metal or polysilicon, which may be biased, thus forming a bias grid. The lateral capacitive deep trench isolation 220 may also laterally insulate the photodetector, for example from other photodetectors, particularly by the presence of insulating trench 221. The capacitive deep trench isolation is said to be lateral since it extends in a direction substantially parallel to the longitudinal direction of the photodetector, level with the lateral edges of the photodetector.

With an N-doped active region, the biasing applied to lateral CDTI 220 is preferably negative. As a variant, if the active region was P-doped, the biasing applied to the lateral CDTI would preferably be positive.

In the example of FIG. 2, repulsion element 230 is shown in the form of a P-doped implant region, for example heavily P-doped, which has the shape of a pillar of substantially square cross-section. Other pillar cross-sections may be envisaged for the implant region, for example a rectangular cross-section or another polygonal cross-section, an oval cross-section, a circular cross-section, or even other shapes than a pillar. The P-doped implant region may be made of silicon, for example may correspond to a P-doped portion of a silicon (Si) layer in which active region 210 is formed.

The implant region may be biased to control its potential, or connected to a floating potential, for example if it is heavily doped, particularly in the case of implant points as described hereafter in another embodiment.

As a variant, instead of an implant region, repulsion element 230 may be an internal capacitive deep trench isolation (CDTI) inserted within active region 210, for example arranged substantially at the center of the active region.

In the example of FIG. 2, repulsion element 230 extends in the Z direction, which here is a vertical direction. As described hereafter in another embodiment, there may be one or a plurality of repulsion elements in another direction, for example a horizontal direction.

The repulsion element does not divide the photodetector into a plurality of distinct volumes, or a plurality of smaller photodetectors, conversely to the pixel with photodetectors of FIG. 1B.

For example, the repulsion element comes into contact with the upper and lower surfaces of the active region over a portion of the width or of the length of the active region, but not over the entire width or length of the active region. For example, the repulsion element does not come into contact with one or the other of the upper or lower surfaces of the active region.

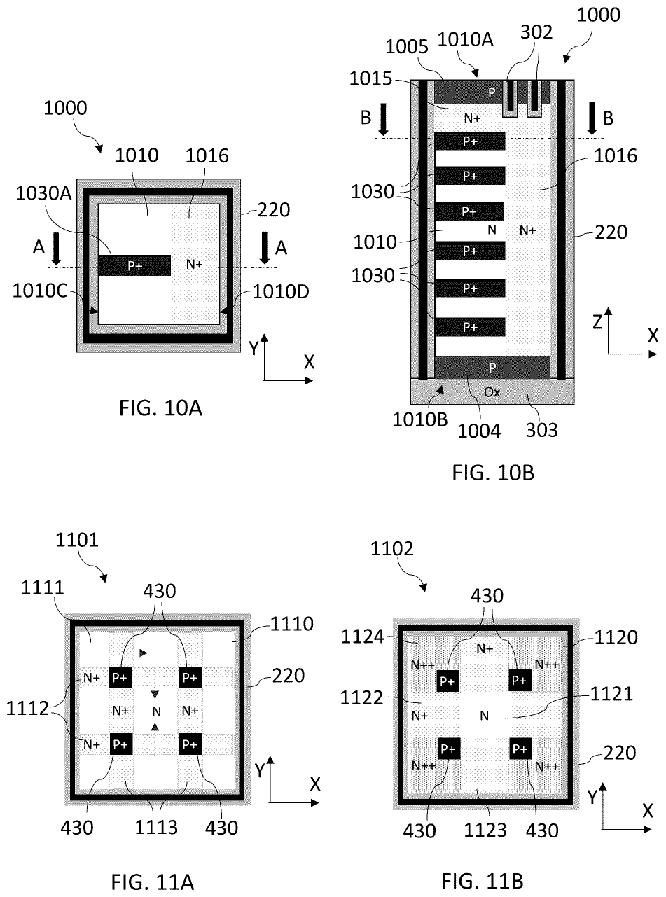

For example, the repulsion element is surrounded by the active region in a plane, for example, an XY plane in the shown example, but it may be another plane, for example, a YZ plane in the embodiment of FIGS. 10A and 10B. In other words, in the cross-section views parallel to this plane, it can be seen that the repulsion element is surrounded by the active region.

By being positioned within the active region, which is of type N (first conductivity type), and being P-doped (second conductivity type opposite to the first conductivity type) in the case of an implant region, or for example negatively biased in the case of an internal CDTI, the repulsion element enables to locally deplete the active region, typically at the junction between the active region and the repulsion element, to avoid the presence of neutral regions in the active region. For example, the repulsion element completes lateral CDTI 220, thus enabling not to have to apply too high a biasing in this lateral CDTI, even when active region 210 is heavily doped. This further avoids increasing the number of pixel or sub-pixel charge readouts, since the binning technique is not applied. Indeed, the repulsion element does not divide the photodetector into a plurality of smaller photodetectors, as indicated hereabove.

FIG. 2 shows a single repulsion element, but the photodetector may advantageously comprise a plurality of repulsion elements within the active region, as described in the following embodiments. The repulsion elements are arranged so that they do not divide the photodetector into a plurality of separate volumes, or photodetector sub-elements. For example, each repulsion element is surrounded by the active region in at least one plane.

FIG. 3A shows, in a top cross-section view, a photodetector 300 according to another embodiment. FIG. 3B shows, in a transverse cross-section view, the photodetector of FIG. 3A. The cross-section view of FIG. 3B is taken along the cross-section plane AA of FIG. 3A. The cross-section view in FIG. 3A is taken along the cross-section plane BB of FIG. 3B.

Photodetector 300 comprises, similarly to the photodetector 200 of FIG. 2, an N-type active region 210, for example N-doped, surrounded by a lateral capacitive deep trench isolation 220 (or external CDTI), but it mainly differs therefrom in that, instead of having a single repulsion element, it comprises a plurality of repulsion elements 330, four in the example, within active region 210. Further, each repulsion element 330 is in the form of an internal capacitive deep trench isolation (CDTI).

Having capacitive deep trench isolations as repulsion elements allows a better electrostatic control as compared with implant regions. It may further be possible to reuse masks used to form lateral capacitive deep trench isolation 220.

Each internal capacitive deep trench isolation 330 comprises an insulating trench 331, for example made of SiO₂, filled with a conductive or semiconductor element 332, such as metal or polysilicon, which may be biased, thus forming a bias grid. With an N-doped active region, the biasing applied to each internal CDTI is preferably negative. As a variant, if the active region was P-doped, the biasing applied to each internal CDTI would preferably be positive.

In the example of FIGS. 3A and 3B, the internal capacitive deep trench isolations 330 are substantially regularly distributed within active region 210, but other configurations will occur to those skilled in the art.

In the example of FIGS. 3A and 3B, each internal capacitive deep trench isolation 330 is shown in the form of a pillar having a substantially square cross-section. Other pillar cross-sections may be envisaged, for example a rectangular or another polygonal cross-section, an oval cross-section, a circular cross-section, or even other shapes than a pillar.

Photodetector 300 further comprises a P-doped region 301 at the upper surface 210A of active region 210, as well as extraction gates 302 (or transfer gates) crossing P-doped region 301. An N-type conductive channel may be formed in a portion of P-doped region 301 when extraction gates 302 are biased, to extract the charges. The lower surface 210B of the active region is insulated by an insulating region 303 (Ox), for example an SiO₂ layer.

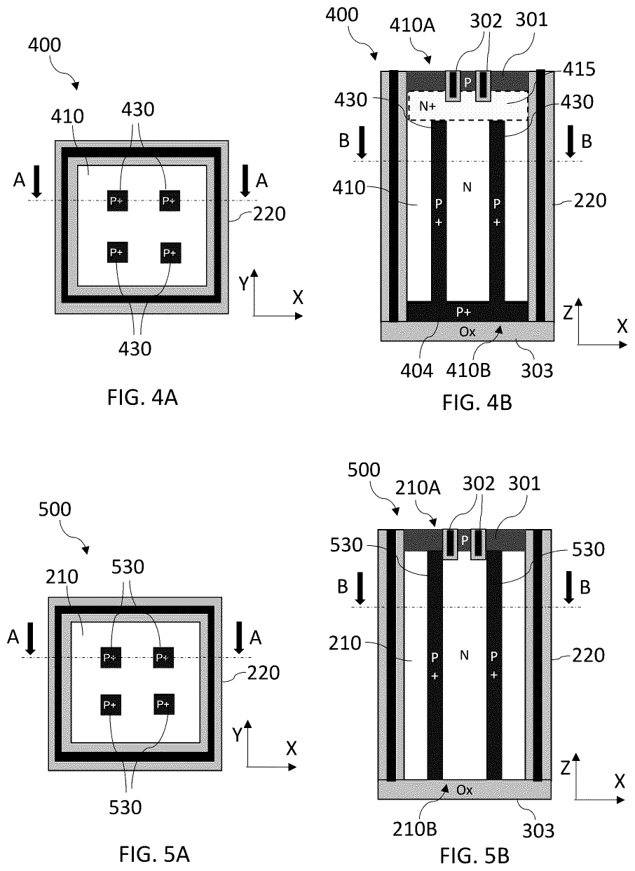

FIG. 4A shows, in a top cross-section view, a photodetector 400 according to another embodiment. FIG. 4B shows, in a transverse cross-section view, the photodetector of FIG. 4A. The cross-section view of FIG. 4B is taken along the cross-section plane AA of FIG. 4A. The cross-section view of FIG. 4A is taken along the cross-section plane BB of FIG. 4B.

Photodetector 400 comprises, similarly to the photodetector 300 of FIGS. 3A and 3B, an N-type active region 410, for example N-doped, surrounded by a lateral capacitive deep trench isolation 220, a P-doped region 301 at the upper surface 410A of active region 410, extraction gates 302, and an insulating region 303 (Ox) at the lower surface 410B of active region 410, but it mainly differs therefrom in that the repulsion elements 430 are P-doped implant regions in the form of pillars (implant pillars), for example heavily P-doped (P+). The characteristics of the implant region described in relation with FIG. 2, as well as the variants, may apply to the repulsion elements 430 of FIGS. 4A and 4B.

In the example of FIGS. 4A and 4B, implant pillars 430 extend in the vertical Z direction from the lower surface 410B (first surface) of active region 410, and more precisely from a heavily P-doped region 404 (P+) located at the lower surface 410B of active region 410 on insulating region 303, but they do not extend all the way to the upper surface 410A (second surface) of active region 410. Heavily P-doped region 404 enables to connect implant regions 430 to one another, for example equipotentially. The fact for implant pillars 430 not to reach the upper surface of the active region, more generally for the implant regions or the repulsion elements not to reach one or a plurality of surfaces of the active region, can enable to eliminate potential barrier problems capable of causing charge remanence.

According to an alternative embodiment shown in dotted lines, a heavily N-doped portion 415 (N+) of active region 410 may be advantageously provided between P-doped region 301 and implant pillars 430. Such a variant allows a better charge collection at the upper surface of the photodetector, for example, by eliminating the charge remanence problem.

FIG. 5A shows, in a top cross-section view, a photodetector 500 according to another embodiment. FIG. 5B shows, in a transverse cross-section view, the photodetector of FIG. 5A. The cross-section view of FIG. 5B is taken along the cross-section plane AA of FIG. 5A. The cross-section view of FIG. 5A is taken along the cross-section plane BB of FIG. 5B.

The photodetector 500 of FIGS. 5A and 5B differs from the photodetector of FIGS. 4A and 4B mainly in that the repulsion elements 530 in the form of implant posts extend in the vertical Z direction from the lower surface 210B to the upper surface 210A of active region 210, and there is no heavily N-doped region between the P-doped region 301 and implant pillars 530. Further, no heavily P-doped (P+) region has been shown at the lower surface 210B of active region 210 on insulating region 303, but the latter may be provided.

Having implant regions as repulsion elements provides a greater flexibility in the dimensions and shapes of the repulsion elements as compared with internal CDTIs, and the ability to collect holes, for example via the application of a contact at the top of the pillars. Further, the implementation of implant regions may be simpler to manufacture than CDTIs.

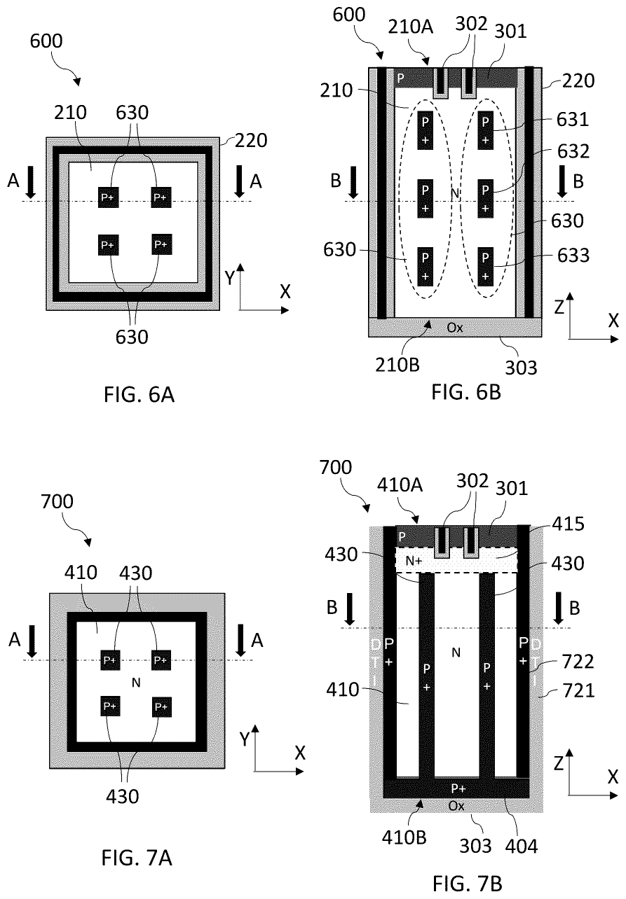

FIG. 6A shows, in a top cross-section view, a photodetector 600 according to another embodiment. FIG. 6B shows, in a transverse cross-section view, the photodetector of FIG. 6A. The cross-section view of FIG. 6B is taken along the cross-section plane AA of FIG. 6A. The cross-section view of FIG. 6A is taken along the cross-section plane BB of FIG. 6B.

The photodetector 600 of FIGS. 6A and 6B differs from the photodetector of FIGS. 5A and 5B mainly in that each implant region 630 does not form a continuous pillar, but forms a discontinuous pillar comprising a plurality of implant points 631, 632, 633 separated from one another by portions of active region 210, for example N-doped Si portions, and extending one above the other in the vertical Z direction.

Having implant points as repulsion elements increases the full well capacity (FWC) with respect to continuous pillars. Indeed, the volume located between two successive implant points may be used as a storage area, effectively maximizing the volume of depleted active region.

The photodetectors of FIGS. 3A, 3B, 5A, and 5B may correspond to photogates.

FIG. 7A shows, in a top cross-section view, a photodetector 700 according to another embodiment. FIG. 7B shows, in a transverse cross-section view, the photodetector of FIG. 7A. The cross-section view of FIG. 7B is taken along the cross-section plane AA of FIG. 7A. The cross-section view in FIG. 7A is taken along the cross-section plane BB of FIG. 7B.

The photodetector 700 of FIGS. 7A and 7B differs from the photodetector of FIGS. 4A and 4B mainly in that lateral CDTI 220 is replaced with a lateral P-doped implant region 722, for example, heavily P-doped (P+), this lateral implant region 722 being insulated from other photodetectors by an insulating trench 721, for example, a deep trench isolation (DTI). The implementation of implant regions may be simpler to manufacture than CDTIs.

In the example of FIGS. 7A and 7B, lateral implant region 722 forms a ring of square cross-section around active region 410, which is parallelepipedal, but other shapes and configurations will occur to those skilled in the art. For example, there may be a plurality of lateral implant regions.

Similarly to the photodetector 400 of FIGS. 4A and 4B, the repulsion elements of photodetector 700 are P-doped implant regions 430, for example heavily P-doped (P+), in the form of continuous pillars which extend in the vertical Z direction from the lower surface 410B (first surface) of active region 410, and more precisely from a heavily P-doped region 404 (P+) located at the lower surface 410B of active region 410 over an insulating region 303, but which do not extend all the way to the upper surface 410A (second surface) of active region 410.

Further, similarly to the photodetector 400 of FIGS. 4A and 4B, a heavily N-doped (N+) portion 415 of active region 410 may be provided between P-doped region 301 and implant pillars 430.

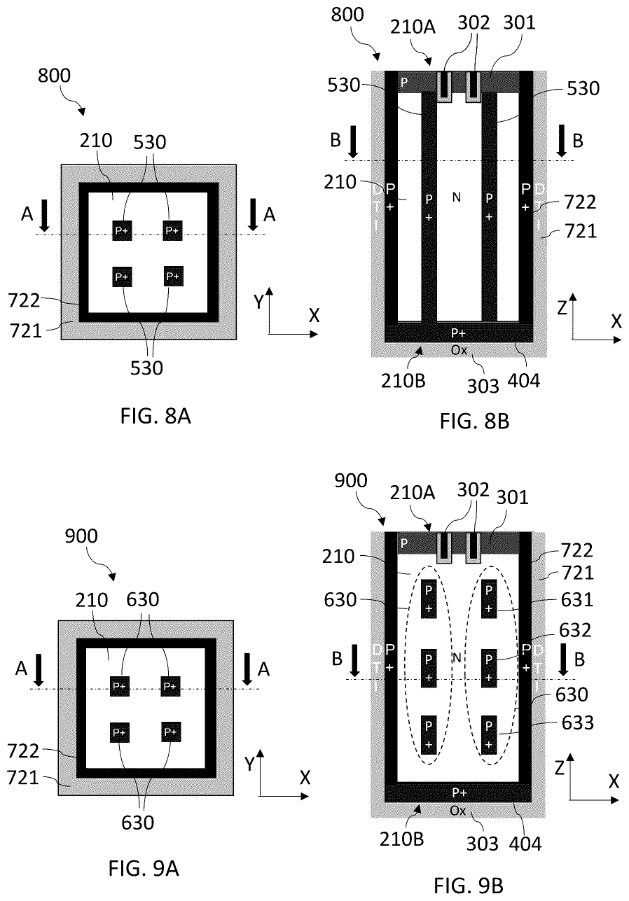

FIG. 8A shows, in a top cross-section view, a photodetector 800 according to another embodiment. FIG. 8B shows, in a transverse cross-section view, the photodetector of FIG. 8A. The cross-section view of FIG. 8B is taken along the cross-section plane AA of FIG. 8A. The cross-section view of FIG. 8A is taken along the cross-section plane BB of FIG. 8B.

The photodetector 800 of FIGS. 8A and 8B differs from the photodetector of FIGS. 5A and 5B mainly in that, similarly to the photodetector of FIGS. 7A and 7B, lateral CDTI 220 is replaced with a lateral P-doped implant region 722, for example, heavily P-doped (P+), this lateral implant region being insulated from other photodetectors by an insulating trench 721, for example, a deep trench isolation (DTI). Photodetector 800 comprises a heavily P-doped (P+) region 404 at the lower surface 210B of active region 210. Similarly to the photodetector 500 of FIGS. 5A and 5B, the repulsion elements of photodetector 800 are P-doped implant regions 530, for example heavily P-doped (P+), in the form of continuous pillars, which extend in the vertical Z direction from the lower surface 210B to the upper surface 210A of active region 210. The lower surface 210B of active region 210 is insulated by an insulating region 303 (Ox).

FIG. 9A shows, in a top cross-section view, a photodetector according to another embodiment. FIG. 9B shows, in a transverse cross-section view, the photodetector of FIG. 9A. The cross-section view of FIG. 9B is taken along the cross-section plane AA of FIG. 9A. The cross-section view of FIG. 9A is taken along the cross-section plane BB of FIG. 9B.

The photodetector 900 of FIGS. 9A and 9B differs from the photodetector of FIGS. 6A and 6B mainly in that, similarly to the photodetector of FIGS. 7A and 7B, lateral CDTI 220 is replaced with a lateral P-doped implant region 722, for example, heavily P-doped (P+), this lateral implant region being insulated from other photodetectors by an insulating trench 721, for example a deep trench isolation (DTI). Similarly to the photodetector 600 of FIGS. 6A and 6B, the repulsion elements of photodetector 900 are P-doped or heavily P-doped implant regions 630, in the form of discontinuous pillars, each comprising a plurality of P-doped or heavily P-doped (P+) implant points 631, 632, 633, separated from one another by portions of active region 210. The lower surface 210B of active region 210 is insulated by an insulating region 303. Photodetector 900 may comprise a heavily P-doped region 404 (P+) on insulating region 303.

FIG. 10A shows, in a top cross-section view, a photodetector 1000 according to another embodiment. FIG. 10B shows, in a transverse cross-section view, the photodetector of FIG. 10A. The cross-section view of FIG. 10B is taken along the cross-section plane AA of FIG. 10A. The cross-section view of FIG. 10A is taken along the cross-section plane BB of FIG. 10B.

The photodetector 1000 of FIGS. 10A and 10B differs from the previous photodetectors mainly in that repulsion elements 1030 extend in a horizontal X direction instead of the vertical Z direction. Repulsion elements 1030 are, for example, six in number, but this is not limiting, and are separated from one another by a non-zero distance in the vertical Z direction, the space between two repulsion elements being filled with portions of active region 1010, for example N-doped silicon, which may be formed by epitaxy.

Similarly to the photodetectors of FIGS. 3A to 6B, photodetector 1000 comprises a lateral CDTI 220 (external CDTI) around active region 1010. As a variant, the lateral CDTI may be replaced with a P-doped lateral implant region, for example heavily P-doped, similarly to the photodetectors of FIGS. 7A to 9B.

Similarly to the photodetectors of FIGS. 3A to 6B, the repulsion elements 1030 of photodetector 1000 are implant regions in the form of pillars, pillars 1030 being oriented horizontally instead of vertically, and the photodetector comprises an insulating region 303 on the lower surface 1010B of active region 1010. Photodetector 1000 further comprises a lower P-doped region 1004 located at the lower surface 1010B of active region 1010 on insulating region 303, an upper P-doped region 1005 located at the upper surface 1010A of active region 1010, and a heavily N-doped portion 1015 (N+) of the active region between upper P-doped region 1005 and upper pillar 1030A.

In the shown example, repulsion elements 1030 start from a first lateral surface 1010C (the left edge in FIG. 10A) of active region 1010 but do not extend all the way to a second lateral surface 1010D opposite to the lateral surface (the right edge in FIG. 10A) of active region 1010, the space between repulsion elements 1030 and the second lateral surface comprising a heavily N-doped region 1016 (N+) of active region 1010. This is a non-limiting example and other variants may be envisaged by those skilled in the art.

The embodiment with horizontal repulsion elements may enable to increase the full well capacity of the active region, even when the latter has a significant height-to-width ratio, for example a small width for a large height.

The different described embodiments show that many variants of photodetectors with repulsion elements in the active region can be envisaged, thus providing a great adaptability to different types and different sizes of photodetectors, and thus of pixels.

More generally than the examples of FIGS. 4A, 4B, 7A, 7B, 10A, 10B, the active region may have a non-homogeneous N (or P in the case of a P-type active region) doping in the vertical Z direction and/or in a horizontal direction. This may enable to avoid remanent charges due to potential barriers, and/or enable to improve the storage of charge carriers, for example at the edges of the photodetector, for example by using the fact that the electrostatic control on the edges of the photodetector is improved due to the distribution of electric field lines and may thus enable to locally deplete a more heavily doped area.

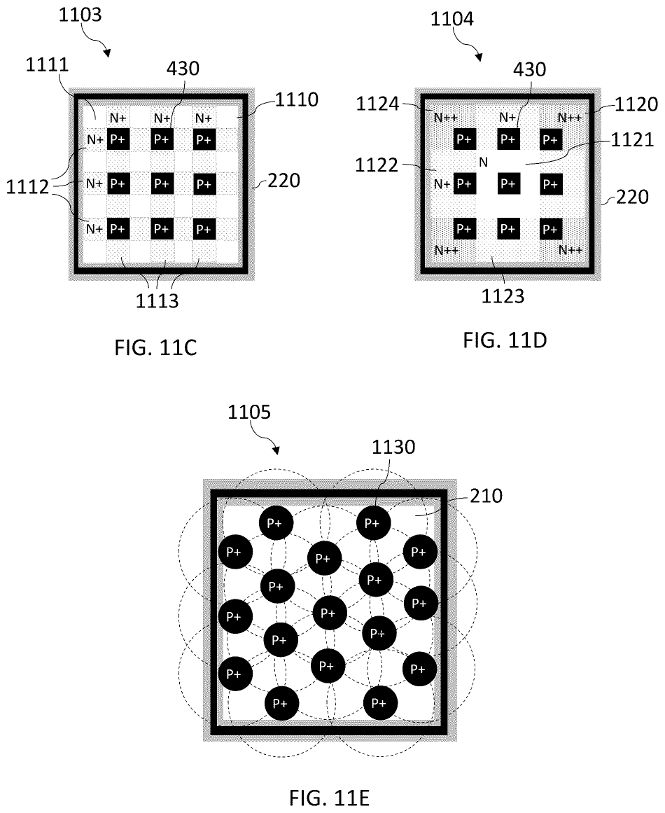

FIG. 11A, FIG. 11B, FIG. 11C, FIG. 11D, and FIG. 11E show, in top cross-section views, photodetectors according to other embodiments. These figures show in particular other configurations of elements of insertion into the active region and other examples of non-homogeneous doping of the active region.

The photodetector 1101 of FIG. 11A differs from the photodetector 400 of FIGS. 4A and 4B mainly in that active region 1110 has a non-homogeneous doping. In this example, active region 1110 comprises first heavily N-doped (N+) strips 1112 extending in the X direction between adjacent implant pillars 430 in this X direction and on either side of these adjacent implant pillars all the way to the lateral edges of active region 1110 which are opposite in this X direction, and second heavily N-doped (N+) strips 1113 extending in the Y direction between adjacent implant pillars 430 in this Y direction and on either side of these adjacent pillars all the way to the lateral edges of active region 1110 which are opposite in this Y direction. The remainder of active region 1110, which is not in the form of heavily N-doped strips 1112, 1113, corresponds to less heavily N-doped portions 1111 of active region 1110.

The photodetector 1102 of FIG. 11B differs from the photodetector 400 of FIGS. 4A and 4B mainly in that active region 1120 is non-homogeneously doped. In this example, active region 1120 comprises very heavily N-doped (N++) corner portions 1124 in the corners of active region 1120, each encompassing an implant pillar 430, a first heavily N-doped (N+) strip 1122 in the X direction between corner portions 1124 all the way to the lateral edges of active region 1120 which are opposite in this X direction, a second heavily N-doped (N+) strip 1123 in the Y direction between the corner regions all the way to the lateral edges of active region 1120 which are opposite in this Y direction, and a less heavily N-doped (N) central portion 1121, which corresponds to the intersection between the first and second strips 1122, 1123.

The photodetector 1103 of FIG. 11C is similar to the photodetector of FIG. 11A, but with nine implant pillars 430 regularly distributed in active region 1110 instead of four in FIG. 11A and thus three first heavily N-doped (N+) strips 1112 extending in the X direction, and three second heavily N-doped (N+) strips 1113 extending in the Y direction. The remainder of the active region 1110, which is not in the form of heavily N-doped strips 1112, 1113, corresponds to less heavily N-doped portions 1111 of active region 1110.

The photodetector 1104 of FIG. 11D is similar to the photodetector of FIG. 11B, but with nine implant pillars 430 regularly distributed in active region 1120 instead of four in FIG. 11B, the very heavily N-doped (N++) corner portions 1124 of active region 1120 encompassing the four most eccentric implant pillars, the first and second strips 1122, 1123 encompassing the four implant pillars positioned between the most eccentric implant pillars in each of the X and Y directions, and the central portion 1121 encompassing a central implant pillar.

The examples of FIGS. 11A and 11C enable, for example, to eliminate local potential barriers, for example linked to a shorter distance between two neighboring pillars. The examples of FIGS. 11B and 11D for example enable to increase the stored charges by improving the charge homogeneity: since it is easier to deplete the active region in corners, the doping is heavier in these corner regions.

The photodetector 1105 of FIG. 11E differs from all the other embodiments in that the implant regions are pillars 1130 of circular cross-section, and in that most of the pillars are arranged substantially equidistantly from one another in active region 210. This configuration may enable to decrease local potential barriers in the active region.

Other configurations than those disclosed in FIGS. 11A to 11E could be envisaged by those skilled in the art, for example according to the number of repulsion elements, for example of vertical implant pillars, and/or according to the desired effect (for example, removing or minimizing potential barriers or increasing the charge homogeneity). Further, instead of one (or a plurality of) external CDTI(s), the photodetectors of FIGS. 11A to 11E may comprise one (or a plurality of) lateral P-doped implant region(s), for example heavily P-doped, insulated from other photodetectors by one (or a plurality of) insulating trench(es).

The photodetectors of FIGS. 11A to 11E may correspond to photogates.

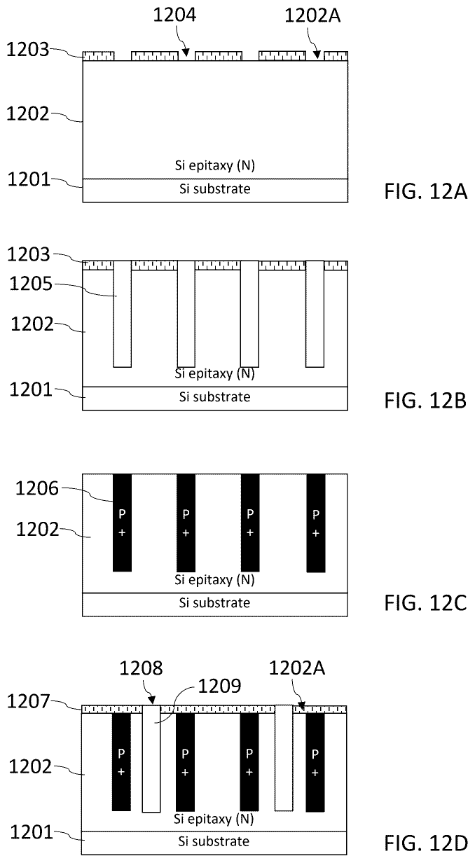

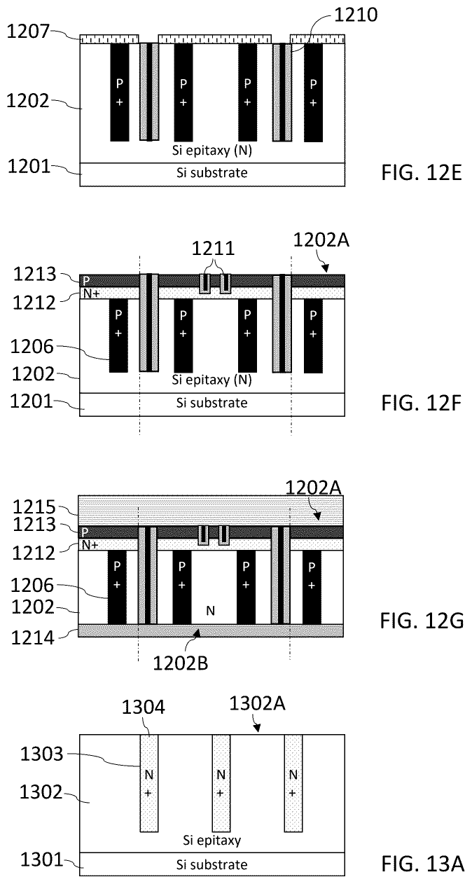

FIG. 12A, FIG. 12B, FIG. 12C, FIG. 12D, FIG. 12E, FIG. 12F, and FIG. 12G show, in transverse cross-section views, steps of an example of a method of manufacturing a photodetector according to an embodiment. The manufactured photodetector may be similar to the photodetector 500 of FIGS. 5A and 5B.

FIG. 12A shows an initial structure comprising a silicon substrate 1201, topped with an N-doped epitaxial silicon layer 1202. A first etch mask 1203 is positioned on the upper surface 1202A of epitaxial silicon layer 1202. Etch mask 1203 comprises first openings 1204.

FIG. 12B shows a structure obtained at the end of the etching of epitaxial silicon layer 1202 from its upper surface 1202A and through the first openings 1204 of first etch mask 1203, so as to form the first trenches 1205 in epitaxial silicon layer 1202. In the shown example, first trenches 1205 do not extend across the entire thickness of this epitaxial silicon layer 1202. As a variant, the first trenches 1205 may extend across the entire thickness of the epitaxial silicon layer 1202 all the way to substrate 1201.

FIG. 12C shows a structure obtained at the end of the filling of the first trenches 1205 by epitaxial growth with heavily P-doped (P+) or even very heavily P-doped silicon, and of the removal of first etch mask 1203. Heavily P-doped implant regions 1206 are thus formed in the form of vertical pillars in an N-doped active region formed by epitaxial silicon layer 1202.

FIG. 12D shows a structure obtained at the end of the forming of a second etch mask 1207 on the upper surface 1202A of epitaxial silicon layer 1202, this second etch mask comprising second openings 1208, and then the forming of second trenches 1209 in epitaxial silicon layer 1202 by etching from its upper surface 1202A and through the second openings 1208 of second etch mask 1207. In the shown example, the second trenches 1209 do not extend across the entire thickness of this epitaxial silicon layer 1202, and extend substantially at the same level as the first trenches 1205 and thus as implant regions 1206. As a variant, the second trenches 1209 may extend across the entire thickness of epitaxial silicon layer 1202 all the way to substrate 1201.

FIG. 12E shows a structure obtained at the end of the forming of capacitive deep trench isolations (CDTI) 1210 in the second trenches 1209. For example, the second trenches 1209 may be insulated from epitaxial silicon layer 1202 by an insulator, for example SiO₂, and then filled with a conductive or semiconductor material, such as a metal or polysilicon, to form capacitive deep trench isolations 1210.

FIG. 12F shows a structure obtained at the end of the removal of second etch mask 1207, of the forming of extraction gate 1211, of a heavily N-doped region 1212 (N+) in epitaxial silicon layer 1202 from the upper surface 1202A of this layer, above vertical implant pillars 1206, and of a P-doped region 1213 on heavily N-doped region 1212.

As a variant, second etch mask 1207 may be removed before the forming of CDTIs 1210.

FIG. 12G shows a structure obtained at the end of the removal of substrate 1201, of the oxidizing of a lower portion of epitaxial silicon layer 1202 so as to form an insulating region 1214 on the lower surface 1202B of epitaxial silicon layer 1202, under vertical implant pillars 1206, and of the assembly of an interconnection substrate 1215 at the upper surface 1202A of epitaxial silicon layer 1202, on P-doped layer 1213.

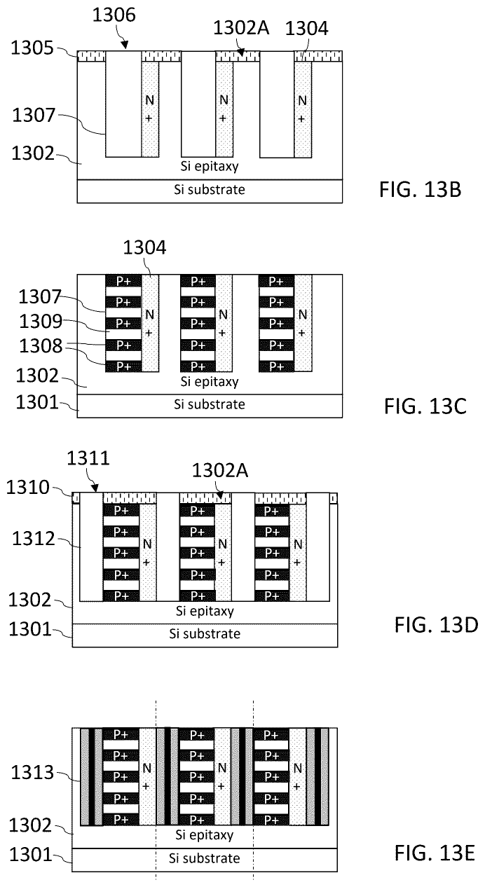

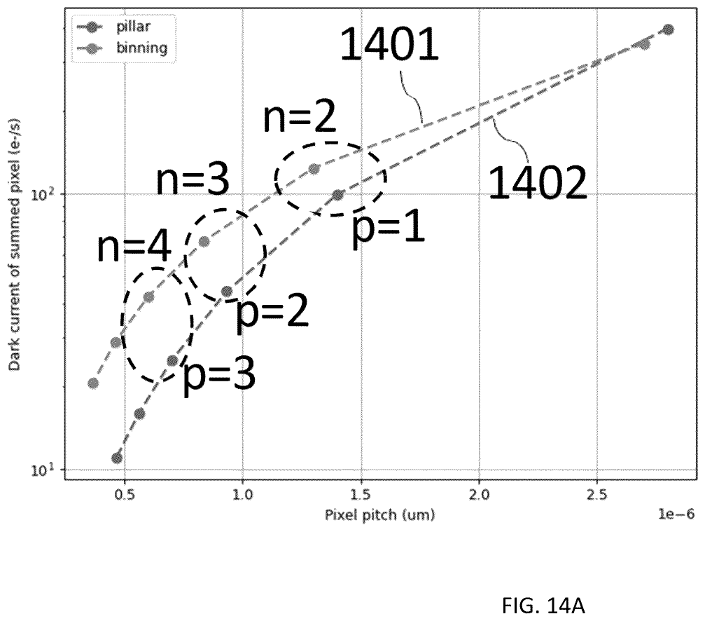

FIG. 13A, FIG. 13B, FIG. 13C, FIG. 13D, and FIG. 13E show, in transverse cross-section views, steps of another example of a method of manufacturing a photodetector according to another embodiment. The manufactured photodetector may be similar to the photodetector 1000 of FIGS. 10A and 10B.

FIG. 13A shows an initial structure comprising a silicon substrate 1301, topped with an N-doped epitaxial silicon layer 1302, in which there have been formed first trenches 1303 filled by epitaxial growth with heavily N-doped silicon so as to form heavily N-doped regions 1304 (N+) in epitaxial silicon layer 1302. The first trenches 1303 may be formed by using a first etch mask, similarly to the first mask 1203 with the first openings 1204 of FIG. 12A. In the shown example, the heavily N-doped regions 1304 do not extend across the entire thickness of this epitaxial silicon layer 1302. As a variant, the heavily N-doped regions 1304 may extend across the entire thickness of epitaxial silicon layer 1302 all the way to substrate 1301.

FIG. 13B shows a structure obtained at the end of the forming of a second etch mask 1305 on the upper surface 1302A of epitaxial silicon layer 1302, this second etch mask comprising second openings 1306, and then the forming of second trenches 1307 in epitaxial silicon layer 1302 by etching from its upper surface 1302A and through the second openings 1306 of second etch mask 1305. In the shown example, the second trenches 1307 do not extend across the entire thickness of epitaxial silicon layer 1302, and extend substantially at the same level as the first trenches 1303 and thus as the heavily N-doped regions 1304. As a variant, the second trenches 1307 may extend across the entire thickness of epitaxial silicon layer 1302 all the way to substrate 1301.

FIG. 13C shows a structure obtained at the end of the forming by epitaxial growth with heavily P-doped (P+) or even very heavily P-doped silicon in the second trenches 1307, of heavily P-doped implant regions 1308 (P+) in the form of horizontal pillars in alternation with N-doped silicon regions 1309, also formed by epitaxial growth.

FIG. 13D shows a structure obtained at the end of the forming of a third etch mask 1310 on the upper surface 1302A of epitaxial silicon layer 1302, this third etch mask comprising third openings 1311, and then the forming of third trenches 1312 in epitaxial silicon layer 1302 by etching from its upper surface 1302A and through the third openings 1311 of third etch mask 1310. In the shown example, the third trenches 1312 do not extend across the entire thickness of epitaxial silicon layer 1302, and extend substantially at the same level as the first and second trenches 1303, 1307. As a variant, the third trenches may extend across the entire thickness of epitaxial silicon layer 1302 all the way to substrate 1301.

FIG. 13E shows a structure obtained at the end of the forming of capacitive deep trench isolations 1313 in the third trenches 1312. For example, the third trenches 1312 may be insulated from epitaxial silicon layer 1302 by an insulator, for example, SiO₂, and then filled with a conductive or semiconductor material, such as a metal or polysilicon, to form capacitive deep trench isolations 1313.

Then, similarly to what is described in relation with FIGS. 12F and 12G, the third etch mask 1310 may be removed, extraction gates may be formed on the upper surface 1302A of epitaxial silicon layer 1302, substrate 1301 may be removed, a lower portion of epitaxial silicon layer 1302 may be oxidized to form an insulating region on the lower surface of epitaxial silicon layer 1302, and an interconnection substrate may be assembled on the upper surface of epitaxial silicon layer 1302.

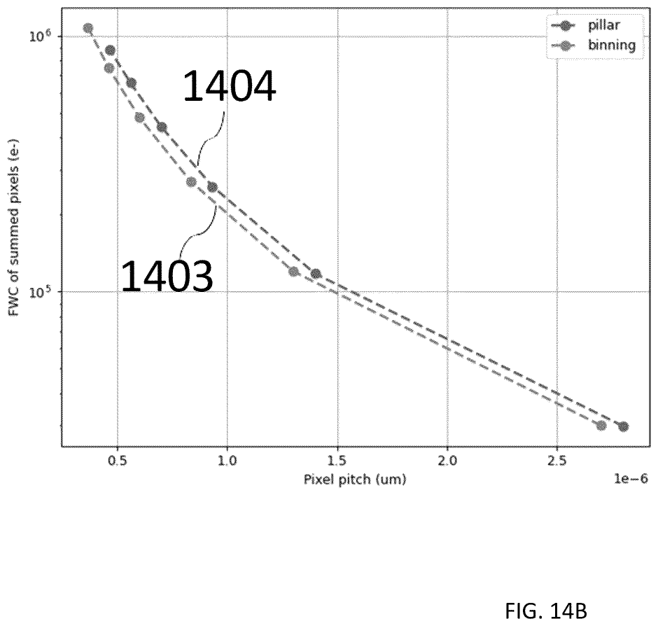

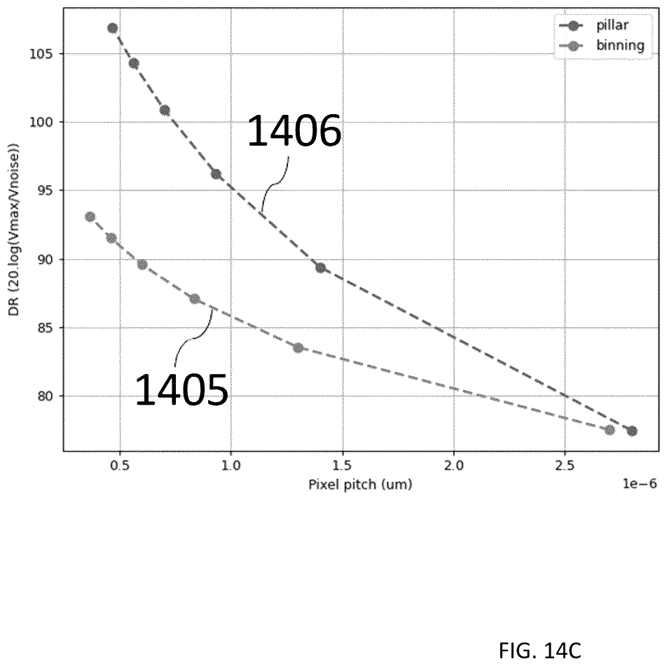

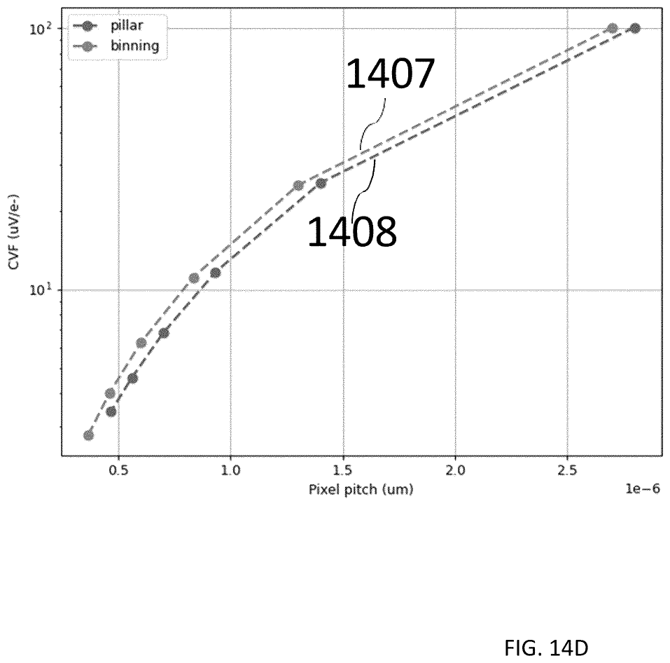

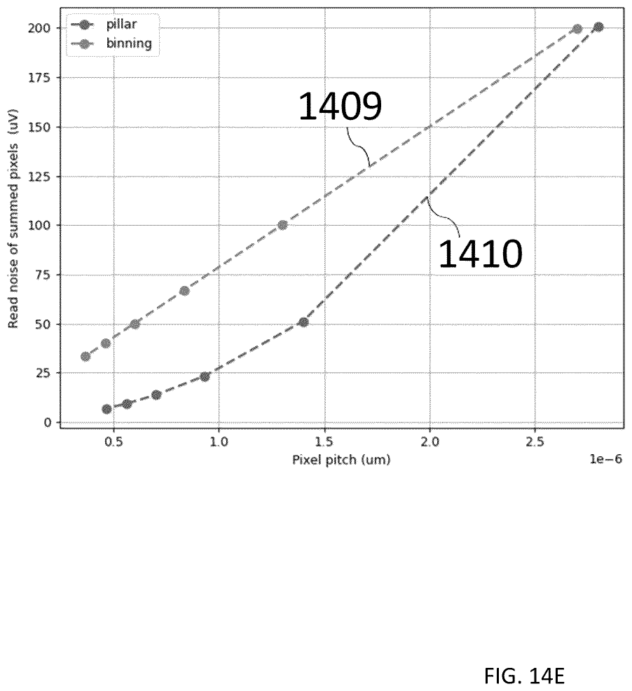

FIG. 14A, FIG. 14B, FIG. 14C, FIG. 14D, and FIG. 14E show curves representing different characteristics of pixel with photodetectors according to embodiments (pillar) as compared with subdivided photodetectors pixels of the type in FIG. 1B (binning).

FIG. 14A shows curves of the dark current of summed pixels according to the pixel pitch in a given direction for pixels with photodetectors of the type in FIG. 1B (curve 1401), as compared with pixels with photodetectors according to embodiments (curve 1402).

The circled points correspond to the number n of subdivisions in the given direction for curve 1401 (or to the number p of wall(s) separating the pixel into n subdivisions in the given direction) and to the number p of pillars in the given direction for curve 1402. The curves show that the dark current is lower for photodetectors according to the embodiments than for photodetectors with binning-type subdivisions, whatever the number of subdivisions/partitions. The embodiments thus enable to decrease the dark current.

FIG. 14B shows curves of the full well capacity (FWC of summed pixels) according to the pixel pitch in the given direction for pixels with photodetectors of the type in FIG. 1B (curve 1403), as compared with pixels with photodetectors according to embodiments (curve 1404). The curves show that an equivalent or even slightly higher full well capacity can be achieved for photodetectors according to embodiments compared with photodetectors with binning-type subdivisions, whatever the number of subdivisions/walls, and this without the disadvantages indicated hereabove for photodetectors with binning-type subdivisions.

FIG. 14C shows curves of the dynamic range (DR) according to the pixel pitch in the given direction for pixel with photodetectors of the type in FIG. 1B (curve 1405) as compared with pixel with photodetectors according to embodiments (curve 1406). The curves show that the dynamic range is greater for photodetectors according to the embodiments than for photodetectors with binning-type subdivisions, whatever the number of subdivisions/partitions. The different embodiments thus enable to increase the dynamic range.

FIG. 14D shows curves of the charge-to-voltage conversion factor (CVF) according to the pixel pitch in the given direction for pixels with photodetectors of the type in FIG. 1B (curve 1407) as compared with pixels with photodetectors according to embodiments (curve 1408). The curves show that an equivalent conversion factor can be achieved for photodetectors according to the embodiments as compared with photodetectors with binning-type subdivisions, whatever the number of subdivisions/partitions, and this, without the disadvantages indicated hereabove of photodetectors with binning-type subdivisions.

FIG. 14E shows curves of the equivalent noise (read noise of summed pixels) according to the pixel pitch in a given direction for pixels with photodetectors of the type in FIG. 1B (curve 1409), as compared with pixels with photodetectors according to embodiments (curve 1410). The curves show that the equivalent noise is lower for photodetectors according to the embodiments than for photodetectors with binning-type subdivisions, whatever the number of subdivisions/partitions. The embodiments thus enable to decrease the equivalent noise, and thus to increase the signal-to-noise ratio.

Various embodiments and variants have been described. Those skilled in the art will understand that certain features of these various embodiments and variants may be combined, and other variants will occur to those skilled in the art. In particular, the active region is of type N in the described examples, the implant regions being of type P, and the CDTIs being for example configured to be negatively biased (electron extraction). As a variant, the active region may be of type P, the implant regions then being of type N, and the CDTIs being for example configured to be positively biased (hole extraction).

Finally, the practical implementation of the described embodiments and variants is within the abilities of those skilled in the art based on the functional indications given hereabove.

1. A semiconductor photodetector, comprising:
an active region made of a doped semiconductor material of a first conductivity type, said active region being configured to convert a light radiation into charge carriers and to store said charge carriers; and
at least one repulsion element configured to repel charge carriers stored in the active region, said repulsion element being positioned within the active region.

2. The photodetector according to claim 1, wherein the at least one repulsion element positioned within the active region is arrange so that the at least one repulsion element does not divide said active region into a plurality of distinct volumes.

3. The photodetector according to claim 1, wherein the at least one repulsion element is surrounded by the active region in at least one plane.

4. The photodetector according to claim 1, wherein the at least one repulsion element comprises a plurality of repulsion elements spaced apart from each other within the active region.

5. The photodetector according to claim 4, wherein the plurality of repulsion elements are regularly distributed in the active region.

6. The photodetector according to claim 5, wherein the plurality of repulsion elements are arranged substantially equidistant from one another.

7. The photodetector according to claim 1, wherein the at least one repulsion element is oriented in a longitudinal direction of the photodetector, wherein said longitudinal direction extends in a depth direction of the active region.

8. The photodetector according to claim 1, wherein the at least one repulsion element is oriented in a transverse direction of the photodetector, wherein said transverse direction extends perpendicular to a depth direction of the active region.

9. The photodetector according to claim 1, wherein the at least one repulsion element has a shape of a continuous pillar.

10. The photodetector according to claim 9, wherein the shape of the continuous pillar has one of: a polygonal cross-section, a rectangular cross-section, a square cross-section, an oval cross-section, or a circular cross-section.

11. The photodetector according to claim 1, wherein the at least one repulsion element comprises a plurality of implant points separated from one another by portions of the active region.

12. The photodetector according to claim 11, wherein the implant points of said plurality of implant points extend one above each other in a longitudinal direction of the photodetector, wherein said longitudinal direction extends in a depth direction of the active region.

13. The photodetector according to claim 11, wherein the portions of the active region forming a discontinuous pillar.

14. The photodetector according to claim 1, wherein the at least one repulsion element extends from a first surface of the active region in depth all the way to a non-zero distance from a second surface of the active region opposite to the first surface; the active region having a portion which extends between said at least one repulsion element and said second surface, said portion being heavily doped with the first conductivity type.

15. The photodetector according to claim 1, wherein the at least one repulsion element is an internal capacitive deep trench isolation.

16. The photodetector according to claim 15, wherein the internal capacitive deep trench isolation is configured to be biased so as to repel stored charge carriers.

17. The photodetector according to claim 1, wherein the at least one repulsion element is a doped implant region of the second conductivity type opposite to the first conductivity type.

18. The photodetector according to claim 1, further comprising a lateral insulating trench configured to laterally insulate said photodetector from adjacent other photodetectors.

19. The photodetector according to claim 18, wherein the lateral insulating trench contains a conductive or semiconductor element, the lateral insulating trench and the conductive or semiconductor element forming a lateral capacitive deep trench isolation.

20. The photodetector according to claim 18, further comprising a lateral implant region between the lateral insulating trench and the active region, the lateral implant region being doped with the second conductivity type opposite to the first conductivity type.

21. The photodetector according to claim 1, wherein the active region has a non-homogeneous doping extending in one or a plurality of transverse directions of the photodetector.

22. An image sensor, comprising a plurality of pixels, wherein each pixel comprises at least one photodetector according to claim 1.
